(19) United States
(12) Patent Application Publication
(10) Pub. No.: US 2023/0242753 A1
(43) Pub. Date: Aug. 3, 2023

(54) THERMOSETTING RESIN COMPOSITION AND CURED PRODUCT THEREOF

(71) Applicants: NIPPON STEEL Chemical & Material Co., Ltd., Tokyo (JP); KUKDO CHEMICAL CO., LTD., Seoul (KR)

(72) Inventors: Masahiro SOH, Tokyo (JP); Kazuo ISHIHARA, Tokyo (JP); Tomoyuki TAKASHIMA, Tokyo (JP); JOONG HWI JEE, Seoul (KR); CHAN HO PARK, Seoul (KR)

(73) Assignees: NIPPON STEEL Chemical & Material Co., Ltd., Tokyo (JP); KUKDO CHEMICAL CO., LTD., Seoul (KR)

(21) Appl. No.: 17/922,972

(22) PCT Filed: Apr. 30, 2021
(86) PCT No.: PCT/JP2021/017169

§ 371 Date: Nov. 3, 2022

(30) Foreign Application Priority Data
May 11, 2020 (JP) 2020-083218

(51) Int. Cl. C08L 63/00

(52) U.S. Cl. CPC C08L 63/00

(57) ABSTRACT

To provide a thermosetting resin composition that provides a cured product excellent in low-dielectric properties, high heat resistance, high adhesiveness, and the like. The thermosetting resin composition includes an aromatic polyhydroxy compound represented by the following formula (1), and a maleimide compound. In the formula, R¹ independently represents a hydrocarbon group having 1 to 8 carbon atoms, R² independently represents a hydrogen atom or a dicyclopentenyl group, and at least one R² is a dicyclopentenyl group; and n represents the number of repetitions and an average value thereof is a number of 1 to 5.

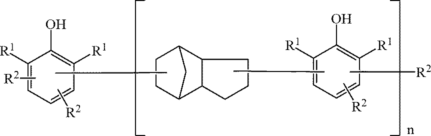

### TECHNICAL FIELD

The present invention relates to a thermosetting resin composition containing, as an essential component, a thermosetting resin that provides a cured product excellent in low dielectric properties, high heat resistance, high adhesiveness, and the like; and a cured product, a sealing material, a material for a circuit substrate, a prepreg, or a laminated board, obtained from the thermosetting resin composition.

### BACKGROUND ART

Thermosetting resins such as an epoxy resin and a phenol resin are excellent in adhesiveness, flexibility, heat resistance, chemical resistance, insulation properties and curing reactivity, and thus are used variously in paints, civil adhesion, cast molding, electrical and electronic materials, film materials, and the like. In particular, epoxy resins, to which flame retardance is imparted, are widely used in applications of printed-wiring substrates as one of electrical and electronic materials.

Portable devices which are one of the applications of printed wiring boards and infrastructure equipment such as base stations that connect them, have been always demanded to have higher performance, accompanying the dramatic increase in information volume in recent years. In particular, the change in communication standards from 4G to 5G is expected to further increase information volume and requires transmission of high-frequency signals. Therefore, a material with a lower dielectric loss tangent has been demanded for printed wiring boards in order to minimize signal attenuation due to high frequencies. Moreover, a matrix resin is required to have characteristics such as high adhesion force and high heat resistance in order to address thinning and multilayers of printed wiring boards. With an aim to meet these requirements, matrix resins using conventional epoxy resins are not sufficient, thereby requiring a thermosetting resin with higher performance.

Regarding lowering of dielectric constants of epoxy resins that have been used as matrix resins for printed circuit substrates, illustrated examples of the raw material epoxy resins include glycidylated compounds of divalent phenol compounds such as bisphenol A, glycidylated compounds of tris(glycidyloxyphenyl)alkane compounds, an aminophenol, and the like, and glycidylated compounds of novolac compounds such as phenol novolac (Patent Literature 1).

Patent Literatures 2 and 3 disclose a method for using an imide group-containing phenol resin in order to improve heat resistance and mechanical properties over epoxy resins and containing the imide group improves heat resistance. Moreover, a compound in which an imide group-containing phenol resin underwent epoxidation is exemplified as a suitable resin for a matrix resin that improves adhesiveness to a base material (Patent Literature 4). Further, Patent Literature 5 exemplifies a composition that has improved heat resistance and flame retardancy of a substrate by using a maleimide compound, an epoxy resin, and a phenol hardener with a specific structure, and Patent Literatures 6 and 7 exemplify to enable a composition excellent in adhesion force and dielectric properties to be provided by using a maleimide compound with a specific structure.

However, none of the epoxy resins disclosed in any of the literatures fully satisfied the requirements for dielectric properties based on the recent trend toward higher functionality and satisfied each physical property simultaneously.

### CITATION LIST

### Patent Literatures

Patent Literature 1: Japanese Patent Laid-Open No. 5-43655
Patent Literature 2: Japanese Patent Laid-Open No. 7-33858
Patent Literature 3: Japanese Patent Laid-Open No. 7-10970
Patent Literature 4: Japanese Patent Laid-Open No. 2010-235823
Patent Literature 5: International Publication No. WO 2011/126070
Patent Literature 6: International Publication No. WO 2016/208667
Patent Literature 7: International Publication No. WO 2020/054526

### SUMMARY OF INVENTION

Accordingly, a problem to be solved by the present invention is to provide a resin composition and a cured product thereof having excellent performance satisfying simultaneously low dielectric properties, high heat resistance, and high adhesiveness, and are useful in applications such as lamination, shape, and adhesion.

The present inventors have found, as a result of diligent experimentation in order to solve the aforementioned problems, that a thermosetting resin composition containing the aromatic polyhydroxy compound represented by the following formula (1) and a maleimide compound, simultaneously satisfies low dielectric properties that are not achieved conventionally, a high glass transition temperature (Tg) and favorable adhesion strength, and thus have completed the present invention.

Namely, the present invention is a thermosetting resin composition containing an aromatic polyhydroxy compound represented by the following general formula (1), and a maleimide compound: [Formula 1]

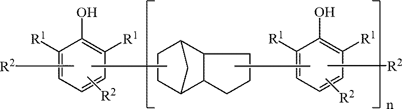

wherein
R¹ independently represents a hydrocarbon group having 1 to 8 carbon atoms,
R² independently represents a hydrogen atom or a dicyclopentenyl group, and at least one R² is a dicyclopentenyl group, and
n represents the number of repetitions and an average value thereof is a number of 1 to 5.

The thermosetting resin preferably further contains an epoxy resin.

Moreover, the present invention is a cured product obtained by curing the resin composition; and a material for a circuit substrate, a sealing material, a prepreg, or a laminated board, using the above resin composition.

The resin composition of the present invention provides a cured product with a high glass transition temperature while maintaining favorable adhesion force of the cured product. Moreover, it is excellent in dielectric properties and exhibits favorable characteristics in a laminated board and an electronic circuit substrate in which a low dielectric constant and a low dielectric loss tangent are demanded.

### BRIEF DESCRIPTION OF DRAWINGS

FIG. 1 A GPC chart of an aromatic polyvalent hydroxy compound obtained in Synthesis Example 1.

FIG. 2 An IR chart of the aromatic polyvalent hydroxy compound obtained in Synthesis Example 1.

FIG. 3 A GPC chart of an epoxy resin obtained in Synthesis Example 4.

### DESCRIPTION OF EMBODIMENTS

Hereinafter, the present invention will be described in detail.

The aromatic polyhydroxy compounds used in the present invention (hereinafter also referred to as phenol resins) are represented by the formula (1) above.

In the general formula (1), R¹ independently represents a hydrocarbon group having 1 to 8 carbon atoms, an alkyl group having 1 to 8 carbon atoms, an aryl group having 6 to 8 carbon atoms, an aralkyl group having 7 to 8 carbon atoms, or an allyl group is preferable. The alkyl group having 1 to 8 carbon atoms may be any of linear, branched and cyclic groups, and examples thereof include a methyl group, an ethyl group, a propyl group, an isopropyl group, a n-butyl group, a t-butyl group, a hexyl group, a cyclohexyl group and a methylcyclohexyl group, but not limited thereto. Examples of the aryl group having 6 to 8 carbon atoms include a phenyl group, a tolyl group, a xylyl group and an ethylphenyl group, but not limited thereto. Examples of the aralkyl group having 7 to 8 carbon atoms include a benzyl group and an α-methylbenzyl group, but not limited thereto. Among these substituents, a phenyl group and an alkyl group having 1 to 3 carbon atoms are preferable from the viewpoint of availability, and reactivity when formed into a cured product, with a methyl group being particularly preferable.

R² independently represents a hydrogen atom and a dicyclopentenyl group and at least one R² is a dicyclopentenyl group. Preferably, R² in a molecule has an average of 0.1 to 1 dicyclopentenyl group per phenol ring.

The dicyclopentenyl group is a group derived from dicyclopentadiene and is represented by the following formula (1a) or formula (1b). [Formula 2]

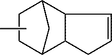

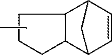

n is the number of repetitions and represents a number of 0 or 1 or more, and the average value (number average) thereof is 1 to 5, preferably 1.1 to 3, more preferably 1.5 to 2.5, and further preferably 1.6 to 2. The content of a n=0 body in terms of GPC is 10% by area or less, the content of a n=1 body is in the range of 50 to 70% by area, and the content of a n=2 or greater body is in the range of 20 to 40% by area.

The molecular weight of the phenol resin is preferably in the range of 400 to 1000 of a weight-average molecular weight (Mw) and in the range of 350 to 800 of a number-average molecular weight (Mn).

The phenol resin preferably has a hydroxyl equivalent of 230 or more, more preferably 240 or more, and it preferably has a softening point of 120° C. or lower and more preferably 110° C. or lower.

The above phenol resin can be obtained, for example, by a reaction of a 2,6-disubstituted phenol compound represented by the following formula (2) with dicyclopentadiene in the presence of a Lewis acid such as a boron trifluoride/ether catalyst.

[Formula 3]

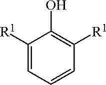

wherein R¹ has the same meaning with the definition in the formula (1) above.

Examples of the 2,6-disubstituted phenol compound include 2,6-dimethylphenol, 2,6-diethylphenol, 2,6-dipropylphenol, 2,6-diisopropylphenol, 2,6-di(n-butyl)phenol, 2,6-di(t-butyl)phenol, 2,6-dihexylphenol, 2,6-dicyclohexylphenol, 2,6-diphenylphenol, 2,6-ditolylphenol, 2,6-dibenzylphenol, 2,6-bis(α-methylbenzyl)phenol, 2-ethyl-6-methylphenol, 2-allyl-6-methylphenol and 2-tolyl-6-phenylphenol, and 2,6-diphenylphenol and 2,6-dimethylphenol are preferable and 2,6-dimethylphenol is particularly preferable from the viewpoints of availability, and reactivity of a cured product obtained.

The catalyst for use in the reaction is a Lewis acid, is specifically, for example, boron trifluoride, a boron trifluoride/phenol complex, a boron trifluoride/ether complex, aluminum chloride, tin chloride, zinc chloride or iron chloride, and in particular, a boron trifluoride/ether complex is preferable in terms of ease of handling. In the case of a boron trifluoride/ether complex, the amount of the catalyst used is 0.001 to 20 parts by mass, preferably 0.5 to 10 parts by mass based on 100 parts by mass of the dicyclopentadiene.

The reaction method for introducing the above dicyclopentenyl group into the 2,6-disubstituted phenol compound is a method for reacting dicyclopentadiene with the 2,6-disubstituted phenol compound at a predetermined ratio, and the dicyclopentadiene may be added continuously or in several stages (successive addition divided into two or more portion), and the reaction may be carried out intermittently. The ratio is 0.25 to 2-fold moles of dicyclopentadiene per mole of the 2,6-disubstituted phenol compound.

The ratio of the dicyclopentadiene to the 2,6-disubstituted phenol compound in a case in which dicyclopentadiene is continuously added and reacted, is 0.25 to 1-fold moles, and it is preferably 0.28 to 1-fold moles, and more preferably 0.3 to 0.5-fold moles. In the case of reacting dicyclopentadiene by successive divided addition, 0.8 to 2-fold moles is preferred overall, and more preferably 0.9 to 1.7-fold moles. Incidentally, the ratio of dicyclopentadiene for use in each stage is preferably 0.28 to 1-fold moles.

The method of confirming introduction of the dicyclopentenyl group into the phenol resin represented by the formula (1) above can be made by using mass spectrometry or FT-IR measurement.

In the case of use of mass spectrometry, for example, electrospray mass spectrometry (ESI-MS) or a field desorption method (FD-MS) can be used. The introduction of the dicyclopentenyl group can be confirmed by subjecting a sample where components different in number of nuclei are separated in GPC or the like, to mass spectrometry.

In the case of use of a FT-IR measurement method, a KRS-5 cell is coated with a sample dissolved in an organic solvent such as THF and such a cell provided with a thin film of the sample, obtained by drying the organic solvent, is subjected to FT-IR measurement, and thus a peak assigned to C—O stretching vibration of a phenol nucleus appears around 1210 cm⁻¹ and a peak assigned to C-H stretching vibration of an olefin moiety of a dicyclopentadiene backbone appears around 3040 cm⁻¹ only in the case of introduction of the dicyclopentenyl group. When one obtained by linearly connecting the start and the end of an objective peak is defined as a baseline and the length from the top of the peak to the baseline is defined as a peak height, the amount of introduction of the dicyclopentenyl group can be quantitatively determined by the ratio (A₃₀₄₀/A₁₂₁₀) of the peak (A₃₀₄₀) around 3040 cm⁻¹ to the peak (A₁₂₁₀) around 1210 cm⁻¹. It can be confirmed that, as the ratio is higher, the values of physical properties are more favorable, and a preferable ratio (A₃₀₄₀/A₁₂₁₀) for satisfaction of objective physical properties is 0.05 or more, more preferably 0.10 or more, particularly preferably 0.10 to 0.30.

The present reaction is favorably made in a manner where the 2,6-disubstituted phenol compound and the catalyst are loaded into a reactor and the dicyclopentadiene is dropped over 1 to 10 hours.

The reaction temperature is preferably 50 to 200° C., more preferably 100 to 180° C., further preferably 120 to 160° C. The reaction time is preferably 1 to 10 hours, more preferably 3 to 10 hours, further preferably 4 to 8 hours.

After completion of the reaction, the catalyst is deactivated by addition of an alkali such as sodium hydroxide, potassium hydroxide, or calcium hydroxide. Thereafter, a solvent, for example, an aromatic hydrocarbon compound such as toluene or xylene or a ketone compound such as methyl ethyl ketone or methyl isobutyl ketone is added for dissolution, the resultant is washed with water, thereafter the solvent is recovered under reduced pressure, and thus an objective phenol resin can be obtained. Preferably, the dicyclopentadiene is reacted in the entire amount as much as possible and some, preferably, 10% or less of the 2,6-disubstituted phenol compound is unreacted and recovered under reduced pressure.

During the reaction, a solvent, for example, an aromatic hydrocarbon compound such as benzene, toluene or xylene, a halogenated hydrocarbon compound such as chlorobenzene or dichlorobenzene, or an ether compound such as ethylene glycol dimethyl ether or diethylene glycol dimethyl ether may be, if necessary, used.

By using such aromatic polyhydroxy compounds, the thermosetting resin compositions of the present invention can be obtained.

The bismaleimide compounds contained in the thermosetting resin composition of the present invention are not particularly limited, and examples include N-phenylmaleimide, N-hydroxyphenylmaleimide, 4,4′-diphenylmethane bismaleimide, polyphenylmethane maleimide, m-phenylene bismaleimide, p-phenylene bismaleimide, 2,2′-[4-(4-maleimidophenoxy)phenyl]propane, 3,3′-dimethyl-5,5′-diethyl-4,4′-diphenylmethane bismaleimide, bis(3,5-dimethyl-4-maleimidophenyl)methane, bis-(3-ethyl-5-methyl-4-maleimidophenyl)methane, bis(3,5-diethyl-4-maleimidophenyl)methane, 4-methyl-1,3-phenylene bismaleimide, 4,4′-diphenyl ether bismaleimide, 4,4′-diphenylsulfone bismaleimide, 1,3-bis(3-maleimidophenoxy)benzene, 1,3-bis(4-maleimidophenoxy)benzene, N,N′-ethylene dimaleimide, N,N′-hexamethylene dimaleimide, maleimide compounds represented by the following formula (3) and the like, prepolymers of these maleimide compounds, or prepolymers of maleimide compounds and amine compounds, and the like.

[Formula 4]

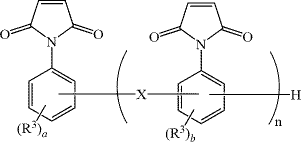

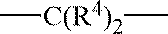

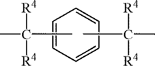

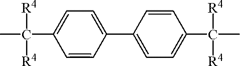

wherein
X is any of formula (3a), (3b), or (3c), and
R³ independently represents an alkyl group having 1 to 5 carbon atoms or an aromatic group.
R⁴ independently represents a hydrogen atom or a methyl group.
a represents 0 to 4 and preferably 0 or 1.
b represents 0 to 3 and preferably 0 or 1.
n is the number of repetitions, and the average value thereof is 1 to 10, with 1 to 5 being preferred.

The thermosetting resin composition of the present invention includes a maleimide compound and a phenol resin, as essential components. The content of the phenol resin relative to 100 parts by mass of the maleimide compound in the resin mixture is preferably 5 to 150 parts by mass, more preferably 10 to 130 parts by mass, and further preferably 20 to 50 parts by mass. As a phenol resin used to obtain the thermosetting resin composition of the present invention, in addition to the aromatic polyhydroxy compound of the present invention, one or two or more types of various phenol resins may be combined for use, as necessary. Preferably, at least 30% by mass of the phenol resin is the aromatic polyhydroxy compound represented by the formula (1) above, and 50% or more thereof is more preferably contained. If the content is less than such values, dielectric properties may be degraded.

Specific examples of phenol resin-based curing agents that can be used in the thermosetting resin compositions of the present invention include phenol compounds mentioned as so called novolac phenol resins, for example, bisphenol compounds such as bisphenol A, bisphenol F, bisphenol C, bisphenol K, bisphenol Z, bisphenol S, tetramethylbisphenol A, tetramethylbisphenol F, tetramethylbisphenol S, tetramethylbisphenol Z, dihydroxydiphenylsulfide and 4,4′-thiobis(3-methyl-6-t-butylphenol), dihydroxybenzene compounds such as catechol, resorcin, methylresorcin, hydroquinone, monomethylhydroquinone, dimethylhydroquinone, trimethylhydroquinone, mono-t-butylhydroquinone and di-t-butylhydroquinone, hydroxynaphthalene compounds such as dihydroxynaphthalene, dihydroxymethylnaphthalene, dihydroxymethylnaphthalene and trihydroxynaphthalene, phosphorus-containing phenol curing agents such as LC-950PM60 (manufactured by Shin-AT&C Co., Ltd.), phenol novolac resins such as Shonol BRG-555 (manufactured by Aica Kogyo Co., Ltd.), cresol novolac resins such as DC-5 (manufactured by NIPPON STEEL Chemical & Material Co., Ltd.), aromatic modified phenol novolac resins, bisphenol A novolac resins, tris-hydroxyphenylmethane-type novolac resins such as Reditop TPM-100 (manufactured by Gunei Chemical Industry Co., Ltd.), condensates of phenol compounds, naphthol compounds and/or bisphenol compounds with aldehyde compounds, such as naphthol novolac resins, condensates of phenol compounds, naphthol compounds and/or bisphenol compounds with xylylene glycol, such as SN-160, SN-395 and SN-485 (manufactured by NIPPON STEEL Chemical & Material Co., Ltd.), condensates of phenol compounds and/or naphthol compounds with isopropenylacetophenone, reaction products of phenol compounds, naphthol compounds and/or bisphenol compounds with dicyclopentadiene, condensates of phenol compounds, naphthol compounds and/or bisphenol compounds with a biphenyl-based crosslinking agent. A phenol novolac resin, a dicyclopentadiene-type phenol resin, a tris-hydroxyphenylmethane-type novolac resin, an aromatic modified phenol novolac resin, and the like are preferable from the viewpoint of availability.

In the case of the novolac phenol resin, examples of the phenol compound include phenol, cresol, xylenol, butyl phenol, amylphenol, nonylphenol, butylmethylphenol, trimethylphenol, and phenylphenol, and examples of the naphthol compound include 1-naphthol and 2-naphthol, and further include the bisphenol compounds, as others. Examples of the aldehyde compound include formaldehyde, acetaldehyde, propylaldehyde, butylaldehyde, valeraldehyde, capronaldehyde, benzaldehyde, chloraldehyde, bromaldehyde, glyoxal, malonaldehyde, succinaldehyde, glutaraldehyde, adipinaldehyde, pimelinaldehyde, sebacinaldehyde, acrolein, crotonaldehyde, salicylaldehyde, phthalaldehyde and hydroxybenzaldehyde. Examples of the biphenyl-based crosslinking agent include bis(methylol)biphenyl, bis(methoxymethyl)biphenyl, bis(ethoxymethyl)biphenyl and bis(chloromethyl)biphenyl.

The thermosetting resin composition of the present invention may contain an epoxy resin in addition to the maleimide compound and phenol resin. The content of the epoxy resin in the thermosetting resin composition is preferably 10 to 80% by mass, and more preferably 20 to 70% by mass. Moreover, the content of the epoxy resin is preferably 10 to 300 parts by mass and more preferably 20 to 280 parts by mass relative to 100 parts by mass of the maleimide compound.

The epoxy resin that is any usual epoxy resin having two or more epoxy groups in its molecule, can be used. Examples include a bisphenol A-type epoxy resin, a bisphenol F-type epoxy resin, a tetramethylbisphenol F-type epoxy resin, a biphenyl-type epoxy resin, a bisphenol fluorene-type epoxy resin, a bisphenol S-type epoxy resin, a bisthio ether-type epoxy resin, a bisnaphthyl fluorene-type epoxy resin, a hydroquinone-type epoxy resin, a resorcinol-type epoxy resin, a naphthalenediol-type epoxy resin, a phenol novolac-type epoxy resin, a styrenated phenol novolac-type epoxy resin, a cresol novolac-type epoxy resin, an alkyl novolac-type epoxy resins, a bisphenol novolac-type epoxy resin, a naphthol novolac-type epoxy resin, a biphenyl aralkyl phenol-type epoxy resin, a β-naphthol aralkyl-type epoxy resin, a dinaphthol aralkyl-type epoxy resin, an α-naphthol aralkyl-type epoxy resin, a naphthalenediol aralkyl-type epoxy resin, a trisphenylmethane-type epoxy resin, a dicyclopentadiene-type epoxy resin, a dicyclopentadiene-type epoxy resin obtained by epoxidizing an aromatic polyhydroxy compound represented by the structural formula (1), an alkylene glycol-type epoxy resin, an aliphatic cyclic epoxy resin, diaminodiphenylmethane tetraglycidylamine, an aminophenol-type epoxy resin, a phosphorus-containing epoxy resin, a urethane-modified epoxy resin, and an oxazolidone ring-containing epoxy resin, but not limited thereto. Moreover, these epoxy resins may be used singly or in combinations of two or more kinds thereof. From the viewpoint of availability, the naphthalenediol-type epoxy resin, the phenol novolac-type epoxy resin, the aromatic-modified phenol novolac-type epoxy resin, the cresol novolac-type epoxy resin, the α-naphthol aralkyl-type epoxy resin, the dicyclopentadiene-type epoxy resin, the phosphorus-containing epoxy resin, and the oxazolidone ring-containing epoxy resins are further preferably used.

Furthermore, the resin composition of the present invention can contain a curing accelerator if necessary. When using the curing accelerator, a compound capable of undergoing a cross-linking reaction with an imide group and a hydroxyl group contained in a hydroxyl group-containing imide compound undergo addition reaction with an imide group, accompanied by cross-linking reaction, thereby exhibiting favorable physical properties.

Examples of the curing accelerators include amine compounds, imidazole compounds, organic phosphine compounds, Lewis acids, and the like, and specific examples thereof include tertiary amines such as 1,8-diaza-bicyclo(5,4,0)undecene-7, triethylenediamine, benzyl dimethylamine, triethanolamine, dimethylaminoethanol, and tris(dimethylaminomethyl)phenol, imidazole compounds such as 2-methylimidazole, 2-phenylimidazole, 2-ethyl-4-methylimidazole, 2-phenyl-4-methylimidazole, and 2-heptadecylimidazole, organic phosphine compounds such as tributylphosphine, methyl diphenylphosphine, triphenylphosphine, diphenylphosphine, and phenylphosphine, addition reaction products of organic phosphine compounds with a quinone compound, tetra-substituted phosphonium tetra-substituted borates such as tetraphenylphosphonium tetraphenylborate, tetraphenylphosphonium ethyltriphenylborate, and tetrabutylphosphonium tetrabutylborate, tetraphenylboronates such as 2-ethyl-4-methylimidazole tetraphenylborate, N-methylmorpholine tetraphenylborate, and the like. The amount added is in the range of 0.2 to 5 parts by mass per 100 parts by mass of the resin composition.

Into the resin composition of the present invention, various additives such as a filler, a silane coupling agent, an antioxidant, a release agent, a defoamer, an emulsifier, a thixotropy imparting agent, a lubricating agent, a flame retardant, a pigment, and the like can be compounded, if necessary.

Specific examples of the filler include molten silica, crystalline silica, alumina, silicon nitride, aluminum hydroxide, boehmite, magnesium hydroxide, talc, mica, calcium carbonate, calcium silicate, calcium hydroxide, magnesium carbonate, barium carbonate, barium sulfate, boron nitride, carbon, a carbon fiber, a glass fiber, an alumina fiber, a silica/alumina fiber, a silicon carbide fiber, a polyester fiber, a cellulose fiber, an aramid fiber, a ceramic fiber, fine particle rubber, a thermoplastic elastomer and a pigment. The reasons for using the filler include the effect of an enhancement in impact resistance. Moreover, when a metal hydroxide such as aluminum hydroxide, boehmite or magnesium hydroxide is used, it has the effect of acting as a flame retardant aid and enhancing flame retardance.

When the resin composition is used as a platy substrate or the like, a fibrous material is a preferred filler in terms of its dimensional stability, bending strength, and the like. More preferably, a glass fiber substrate using a filler of a fibrous base material made of glass fibers woven into a mesh-like structure is included.

The amount of compounding of the filler compounded is preferably in the range of 1 to 150 parts by mass and more preferably 10 to 70 parts by mass relative to 100 parts by mass of the resin composition (solid content). When the amount of compounding is large, a cured material may become brittle and sufficient mechanical properties may not be obtained. A small amount of compounding is liable not to have any effect by compounding of a filler, for example, an enhancement in impact resistance of the cured product.

The amount of compounding of other additives is preferably in the range of 0.01 to 20 parts by mass relative to 100 parts by mass of the resin composition (solid content).

The resin composition of the present invention can be heated and cured to obtain a cured product. The method for obtaining the cured product is a method suitably used such as cast molding, compression molding, transfer molding or the like, or laminating the resin compositions in a form of a resin sheet, copper foil with a resin, or prepreg, and then curing with heating and pressurizing to form a laminated board. The temperature in this case is usually in the range of 150 to 300° C., and the curing time is usually approximately 10 minutes to 5 hours.

The resin composition of the present invention is obtained by uniformly mixing each of the above components. The resin composition can be easily formed into a cured product by the same method as that conventionally known. Examples of the cured product include formed cured products such as a laminated product, a cast molded product, a shaped product, an adhesion layer, an insulation layer and a film.

Applications for which the resin composition is used include a printed circuit substrate material, a resin composition for flexible circuit substrates, an insulation material for a circuit substrate such as an interlayer insulation material for build-up boards, a semiconductor sealing material, conductive pastes, conductive films, adhesive films for build-up, resin casting materials, adhesives, and the like. Among these various applications, in the applications of the printed wiring board material, insulation material for a circuit substrate, and adhesive films for build-ups can be used as insulation materials for a substrate for so-called electronic component embedding where passive components such as capacitors and active components such as IC chips are embedded within the substrate. Among them, the resin composition is preferably used for resin compositions for printed wiring board materials and flexible wiring boards, materials for circuit substrate materials (laminated boards) such as interlayer insulation materials for build-up boards, and a semiconductor sealing material, from its characteristics such as high flame retardancy, high heat resistance, low dielectric properties, and solvent solubility.

Sealing materials obtained by using the resin composition of the present invention include a sealing tape for semiconductor chips, sealing materials for potting-type liquid sealing, underfills, interlayer insulation films for semiconductors, and the like, and can be suitably used for these materials. In order to prepare the resin composition for semiconductor sealing materials, a method for pre-mixing additives such as an inorganic filler, a coupling agent, or a mold release agent, which is added as necessary in the resin composition, and then sufficiently melt-mixing it until becoming uniform by using an extruder, a kneader, rolls, or the like, is included. In this case, silica is usually used as the inorganic filler, and the inorganic filler is preferably compounded in an amount of 70 to 95% by mass in the resin composition.

When the resin composition thus obtained is used as a semiconductor package, a method for cast molding the resin composition, or molding it by using a transfer molding machine, injection molding machine, or the like, and further heating and curing it at 180 to 250° C. for 0.5 to 5 hours to obtain a molded product. When the resin composition is used as a tape-like sealing material, a method can be exemplified which includes heating the resin composition to thereby produce a semi-cured sheet and form the sheet into a sealing material tape, then disposing the sealing material tape on a semiconductor chip and heating the tape to 100 to 150° C. for softening and molding, and completely curing the resultant at 180 to 250° C. Moreover, when used as a potting-type liquid sealing material, the resin composition obtained may be dissolved in a solvent as necessary, then applied onto a semiconductor chip or an electronic component and cured directly.

The resin composition of the present invention can be prepared in varnish form by dissolving it in an organic solvent. The organic solvents that can be used include alcohol-based solvents such as methanol and ethanol, ketone-based solvents such as acetone, methyl ethyl ketone, methyl isobutyl ketone, and cyclohexanone, ether-based solvents such as tetrahydrofuran, nitrogen atom-containing solvents such as dimethylformamide, dimethylacetamide, and N-methylpyrrolidone, sulfur atom-containing solvents such as dimethyl sulfoxide, and the like, and one or more thereof can be mixed for use. They are not particularly limited as long as they are industrially available, and methyl ethyl ketone and dimethyl formamide are preferred from the viewpoints of solubility and handleability.

The resin composition of the present invention can be formed into a prepreg by preparing a composition varnish dissolved in an organic solvent, then impregnating it in a fibrous material such as a glass cloth, an aramid nonwoven fabric, a polyester nonwoven fabric such as a liquid crystal polymer, or the like, and subsequently removing the solvent. Moreover, a surface of a sheet such as a copper foil, a stainless steel foil, a polyimide film, or a polyester film, is coated with the composition varnish and then the coated sheet is dried to form into an adhesive sheet.

When forming a laminated board using the aforementioned prepreg, one or plural sheets of prepregs are laminated, a metal foil is arranged on one or both sides of the prepreg to form a laminate, which was heated and pressurized to cure and integrate the prepreg, enabling a laminate board to be obtained. Here, as the metallic foil, a single, alloy, or composite metallic foil of copper, aluminum, brass, nickel, or the like can be used. The conditions under which the laminate is heated and pressurized may be appropriately adjusted accordingly to the conditions under which the resin composition is cured, however, if the pressurization is too low, bubbles may remain inside the resulting laminate board, which may deteriorate electrical properties, whereby the laminate is desirably pressurized under conditions satisfying shapeability. The heating temperature is preferably 160 to 250° C., more preferably 170 to 220° C. The pressure applied is preferably 0.5 to 10 MPa, more preferably 1 to 5 MPa. The heating and pressurizing time is preferably 10 minutes to 4 hours, more preferably 40 minutes to 3 hours. Furthermore, a single-layered laminated board thus obtained can serve as an inner layer material, to thereby produce a multi-layered board. In this case, the laminated board first undergoes circuit formation according to an additive method, a subtractive method or the like, and a circuit-formed surface is blackened to obtain an inner layer material. An insulation layer is formed on one of side of this inner layer material or both sides of the circuit-formed surface, with the prepreg or the adhesive sheet, and also a conductor layer is formed on a surface of the insulation layer, thereby forming a multi-layered board.

### EXAMPLES

The present invention is specifically described with reference to Examples and Comparative Examples, but the present invention is not limited thereto. Unless particularly noted, “parts” represents “parts by mass”, “%” represents “% by mass”, and “ppm” represents “ppm by mass”. Measurement methods were respectively the following measurement methods.
Hydroxyl equivalent: measured in accordance with JIS K 0070 standard, where the unit was expressed by “g/eq.”. Unless particularly noted, the hydroxyl equivalent of an aromatic polyvalent hydroxy compound means the phenolic hydroxyl equivalent.
Softening point: measured in accordance with a ring-and-ball method in JIS K 7234 standard. Specifically, an automatic softening point apparatus (ASP-MG4 manufactured by Meitech Company, Ltd.) was used.
Copper foil peel strength and interlayer adhesion force: measured in accordance with JIS C 6481. The interlayer adhesion force was measured by pulling and peeling between the seventh layer and the eighth layer.
Relative permittivity and dielectric tangent: evaluated by determining the relative permittivity and the dielectric tangent at a frequency of 1 GHz by a capacitance method according to IPC-TM-650 2.5.5.9 by use of a material analyzer (manufactured by AGILENT Technologies).
Glass transition temperature (Tg): measured in accordance with JIS C 6481. Tg is denoted in terms of a tan δ peak top when measurement was carried out with a dynamic viscoelasticity measuring apparatus (EXSTAR DMS6100, manufactured by Hitachi High-Tech Science Corporation) under the condition of a rate of temperature rise of 5° C./minute).
GPC (gel permeation chromatography) measurement: columns (TSKgelG4000H_{XL}, TSKgelG3000H_{XL} and TSKgelG2000H_{XL} manufactured by Tosoh Corporation) connected to the main body (HLC-8220 GPC manufactured by Tosoh Corporation) in series were used, and the column temperature was 40° C. The eluent here used was tetrahydrofuran (THF) at a flow rate of 1 mL/min, and the detector here used was a differential refractive index detector. The measurement specimen here used was 50 µL of one obtained by dissolving 0.1 g of a sample in 10 mL of THF and filtering the solution by a micro filter. GPC-8020 Model II version 6.00 manufactured by Tosoh Corporation was used for data processing.
IR: the absorbance at a wavenumber of 650 to 4000 cm<SUP>-1 </SUP>was measured with a Fourier transform infrared spectrometer (Spectrum One FT-IR Spectrometer 1760X manufactured by Perkin Elmer Precisely) and KRS-5 as a cell by coating the cell with a sample dissolved in THF and drying the resultant.
ESI-MS: mass analysis was performed by subjecting a sample dissolved in acetonitrile to measurement with a mass spectrometer (LCMS-2020 manufactured by Shimadzu Corporation) by use of acetonitrile and water in a mobile phase.

Abbreviations used in Examples and Comparative Examples are as follows.

### Maleimide Compounds

M1: Phenylmethane maleimide (BMI-2300, manufactured by DAIWA KASEI KOGYO CO. LTD.)
M2: The maleimide resin obtained in Synthesis Example 5

### Aromatic Polyvalent Hydroxy Compound

P1: Aromatic polyvalent hydroxy compound obtained in Synthesis Example 1
P2: Aromatic polyvalent hydroxy compound obtained in Synthesis Example 2
P3: Aromatic polyvalent hydroxy compound obtained in Synthesis Example 3
P4: A dicyclopentadiene-type phenol resin (GDP-6140, hydroxyl group equivalent 196, softening point 130° C., manufactured by Gunei Chemical Industry Co., Ltd.)
P5: A biphenyl aralkyl-type phenol resin (MEH-7851, hydroxyl group equivalent 223, manufactured by Meiwa Kasei Industries, Ltd.)

### Epoxy Resins

E1: The epoxy resin obtained in Synthesis Example 4
E2: A biphenyl aralkyl-type epoxy resin (NC-3000, epoxy equivalent 274, softening point 60° C., manufactured by Nippon Kayaku Co., Ltd.)

### Curing Accelerator

C1: 2-Ethyl-4-methylimidazole (CUREZOL 2E4MZ, manufactured by Shikoku Kasei Kogyo Kabushiki Kaisha)

### Synthesis Example 1

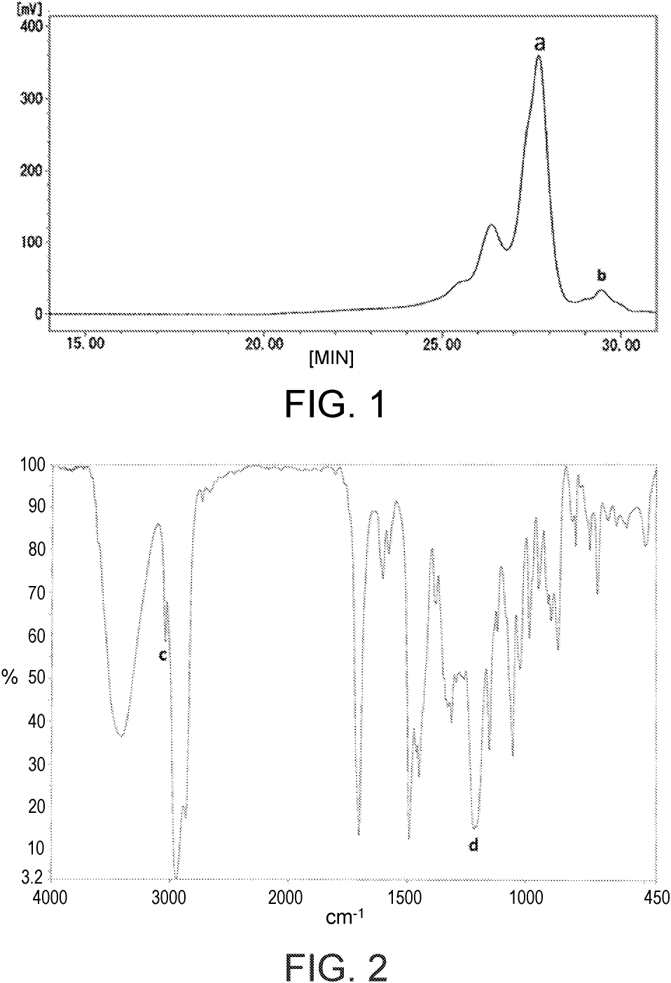

A reaction apparatus including a separable flask of glass, equipped with a stirrer, a thermometer, a nitrogen blowing tube, a dropping funnel and a cooling tube was loaded with 140 parts of 2,6-xylenol and 9.3 parts of a 47% BF₃ ether complex (0.1-fold moles relative to dicyclopentadiene first added), and the resulting mixture was warmed to 110° C. with stirring. While this temperature was kept, 86.6 parts of dicyclopentadiene (0.57-fold moles relative to 2,6-xylenol) was dropped for 1 hour. Furthermore, the reaction was made at a temperature of 110° C. for 3 hours, and thereafter, while this temperature was kept, 68 parts of dicyclopentadiene (0.44-fold moles relative to 2,6-xylenol) was dropped for 1 hour. Furthermore, the reaction was made at a temperature of 120° C. for 2 hours. Thereto was added 14.6 parts of calcium hydroxide. Furthermore, 45 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. The product was dissolved by addition of 700 parts of methyl isobutyl ketone (MIBK), and washed with water by addition of 200 parts of warm water at 80° C., and an aqueous layer as the lower layer was separated and removed. Thereafter, MIBK was evaporated and removed by warming to 160° C. under a reduced pressure of 5 mmHg, and thus 274 parts of red-brown aromatic polyvalent hydroxy compound (P1) was obtained. The hydroxyl equivalent was 299, the resin had a softening point of 97° C., and the absorption ratio (A₃₀₄₀/A₁₂₁₀) was 0.17. A mass spectrum by ESI-MS (negative) was measured, and the following was confirmed: M- = 253, 375, 507, 629. The GPC chart of the obtained aromatic polyhydroxy compound (P1) is shown in FIG. 1 and the FT-IR is shown in FIG. 2, respectively. The Mw by GPC was 690, Mn was 510, content of the n=0 body was 6.5% by area, content of the n=1 body 61.5% by area, and content of the n=2 or greater body 32.0% by area. The mixture of the n=1 body of the formula (1) and the n=1 body without the R² adduct of the formula (1) are shown in FIG. 1a, and the n=0 body of the formula (1) is shown in FIG. 1b. In FIG. 2, c corresponds to a peak assigned to C—H stretching vibration of an olefin moiety of a dicyclopentadiene backbone, and d means absorption due to C—O stretching vibration of a phenol nucleus.

### Synthesis Example 2

The same reaction apparatus as in Synthesis Example 1 was loaded with 140 parts of 2,6-xylenol and 9.3 parts of a 47% BF₃ ether complex (0.1-fold moles relative to dicyclopentadiene initially added), and the resulting mixture was warmed to 110° C. with stirring. While this temperature was kept, 86.6 parts of dicyclopentadiene (0.57-fold moles relative to 2,6-xylenol) was dropped for 1 hour. Furthermore, the reaction was made at a temperature of 110° C. for 3 hours, and thereafter, while this temperature was kept, 90.6 parts of dicyclopentadiene (0.60-fold moles relative to 2,6-xylenol) was dropped for 1 hour. Furthermore, the reaction was made at a temperature of 120° C. for 2 hours. Thereto was added 14.6 parts of calcium hydroxide. Furthermore, 45 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. The product was dissolved by addition of 740 parts of MIBK, and washed with water by addition of 200 parts of warm water at 80° C., and an aqueous layer as the lower layer was separated and removed. Thereafter, MIBK was evaporated and removed by warming to 160° C. under a reduced pressure of 5 mmHg, and thus 310 parts of red-brown aromatic polyvalent hydroxy compound (P2) was obtained. The hydroxyl equivalent was 341, the resin had a softening point of 104° C., and the absorption ratio (A₃₀₄₀/A₁₂₁₀) was 0.27. A mass spectrum by ESI-MS (negative) was measured, and the following was confirmed: M- = 253, 375, 507, 629. The Mw by GPC was 830, Mn was 530, content of the n=0 body was 5.9% by area, content of the n=1 body was 60.1% by area, and content of the n=2 or greater body was 34.0% by area.

### Synthesis Example 3

The same reaction apparatus as in Synthesis Example 1 was loaded with 140 parts of 2,6-xylenol and 9.3 parts of a 47% BF₃ ether complex (0.1-fold moles relative to dicyclopentadiene first added), and the resulting mixture was warmed to 110° C. with stirring. While this temperature was kept, 86.6 parts of dicyclopentadiene (0.57-fold moles relative to 2,6-xylenol) were dropped for 1 hour. Furthermore, the reaction was made at a temperature of 110° C. for 3 hours, then 34.0 parts of dicyclopentadiene (0.22-fold moles relative to 2,6-xylenol) was dropped for 1 hour while keeping the same temperature. Furthermore, the reaction was made at 120° C. for 2 hours. Thereto was added 14.6 parts of calcium hydroxide. Furthermore, 45 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. The product was dissolved by addition of 608 parts of MIBK, and washed with water by addition of 200 parts of warm water at 80° C., and an aqueous layer as the lower layer was separated and removed. Thereafter, MIBK was evaporated and removed by warming to 160° C. under a reduced pressure of 5 mmHg, and thus 253 parts of red-brown aromatic polyvalent hydroxy compound (P3) was obtained. The hydroxyl group equivalent was 243, the resin had a softening point of 92° C., and the absorption ratio (A₃₀₄₀/A₁₂₁₀) was 0.11. Measurement of mass spectra by ESI-MS (negative) confirmed that that M- = 253, 375, 507, and 629. The Mw by GPC was 460, Mn was 380, content of the n=0 body was 5.6% by area, content of the n=1 body was 5.6% by area, and content of the n=2 or greater body was 28.0% by area.

### Synthesis Example 4

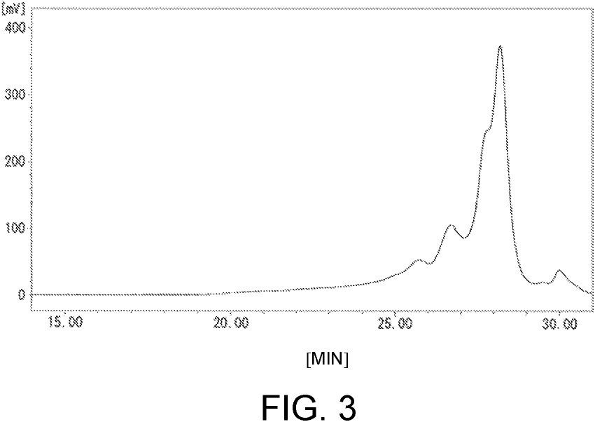

The same reaction apparatus as in Synthesis Example 1 was loaded with 100 parts of the aromatic polyhydroxy compound (P1) obtained in Synthesis Example 1, 155 parts of epichlorohydrin and 46 parts of diethylene glycol dimethyl ether and the resulting mixture was warmed to 65° C. Under a reduced pressure of 125 mmHg, 30.9 parts of a 49% sodium hydroxide aqueous solution was dropped for 4 hours while keeping the temperature at 63 to 67° C. During this time, epichlorohydrin was azeotropized with water, and the effluent water was sequentially removed from the system. After completion of the reaction, epichlorohydrin was collected under the conditions of 5 mmHg and 180° C., and a product was dissolved by addition of 277 parts of MIBK. Thereafter, 80 parts of water were added to dissolve a byproduct salt, and brine as the lower layer was separated and removed in a stationary state. After neutralized with a phosphoric acid aqueous solution, the resin solution was washed with water until the aqueous solution reached neutral followed by filtered. Under a reduced pressure of 5 mmHg, MIBK was distilled off by warming the solution to 80° C. then to obtain 113 parts of a reddish brown transparent 2,6-xylenol dicyclopentadiene-type epoxy resin. It was a resin having an epoxy equivalent of 358, total chlorine content of 520 ppm, and a softening point of 80° C. The Mw by GPC was 870 and Mn was 570. The GPC chart of the obtained epoxy resin (E1) is shown in FIG. 3.

### Synthesis Example 5

A flask equipped with a thermometer, a cooling tube, a Dean Stark azeotropic distillation trap, and a stirrer was loaded with 100 parts of aniline and 50 parts of toluene, and 39.2 parts of 35% hydrochloric acid was dropped at room temperature for 1 hour. After completion of the dropping followed by heating, water and toluene that underwent azeotropic distillation by the heating were cooled and separated, and then only the toluene that was an organic layer, was returned to the system for dehydration. Next, 33.6 parts of 4,4′-bis(chloromethyl)biphenyl were added over 1 hour while keeping at 60 to 70° C., and the reaction was made for another 2 hours at the same temperature. After completion of the reaction, toluene was removed while raising the temperature to reach a temperature in the system to 195 to 200° C., and the reaction was made at this temperature for 15 hours. Thereafter, 86 parts of a 30% sodium hydroxide aqueous solution were slowly dropped while cooling down, so as not to allow the system to reflux violently, toluene that was distilled off upon raising the temperature at or below 80° C., was returned to the system and it was allowed to stand undisturbed at 70° C. to 80° C. The separated lower aqueous layer was removed and the reaction solution was washed with water repeatedly until the washing liquid reached neutral. Next, a rotary evaporator was used to remove an excess aniline and toluene from the oil layer under heating and reduced pressure (200° C., 0.6 KPa), thereby obtaining 47 parts of an aromatic amine resin.

Next, the aforementioned flask was loaded with 75 parts of maleic anhydride and 150 parts of toluene, and water and toluene that underwent azeotropic distillation by the heating were cooled and separated, then only the toluene that was an organic layer was returned to the system for dehydration. Next, a resin solution obtained by dissolving 100 parts of the above aromatic amine resin in 100 parts of N-methyl-2-pyrrolidone was dropped over 1 hour while keeping the temperature in the system at 80 to 85° C. After completion of the dropping, the reaction was made for 2 hours at the same temperature, 1.5 parts of p-toluenesulfonic acid was added, and condensed water and toluene that underwent azeotropic distillation under the reflux conditions were cooled and separated, then only the toluene that was an organic layer was returned to the system, and the reaction was made for 20 hours with dehydration. After completion of the reaction, 100 parts of toluene were added, the mixture was repeatedly washed with water to remove p-toluenesulfonic acid and excess maleic anhydride and heated to remove water from the system by azeotropic distillation. The reaction solution was then concentrated to yield 133 parts of a maleimide resin.

### Example 1

100 parts of maleimide M1, 40 parts of the resin obtained in Synthesis Example 1, and 1.5 parts of 2E4MZ were compounded, and the mixture was dissolved in methyl ethyl ketone (MEK) to obtain a resin composition varnish with a resin concentration of 50%.

A glass cloth (WEA 7628 XS13 manufactured by Nitto Boseki Co., Ltd., 0.18 mm in thickness) was impregnated with the resin composition varnish obtained. The glass cloth impregnated was dried in a hot air oven at 150° C. for 10 minutes, to thereby obtain a prepreg. The resulting 8 sheets of prepregs were stacked with copper foils (3EC-III, 35 µm thick, manufactured by MITSUI MINING & SMELTING CO., LTD.) on the top and bottom of the sheets, underwent vacuum pressing at 2 MPa under the temperature conditions of 130° C. × 15 minutes + 220° C. × 120 minutes to obtain a laminated board with a thickness of 1.6 mm. Table 1 shows the measurement results of the copper foil peeling strength and Tg of the laminated board.

Moreover, the obtained prepreg was unraveled and sieved to powdery prepreg powder with a 100 mesh pass. The obtained prepreg powder was fed in a fluororesin mold, and was subjected to vacuum pressing at 2 MPa under the temperature conditions of 130° C. × 15 minutes + 220° C. × 120 minutes to obtain a cured resin test piece with a square of 50 mm × a thickness of 2 mm. Table 1 shows the measurement results of the dielectric constant and dielectric loss tangent of the test piece.

### Examples 2 to 7, Comparative Examples 1 to 5

Each of resin composition varnishes was obtained by compounding the components in the compounding amounts (parts) in Table 1, using the same apparatus as in Example 1 under the same procedure, and furthermore, a laminated board and cured resin test pieces were obtained. The same test as in Example 1 was conducted, and the results are shown in Table 1.

TABLE 1

| | Examples | | | | | | | Comparative Examples | | | | |
|---|---|---|---|---|---|---|---|---|---|---|---|---|
| | 1 | 2 | 3 | 4 | 5 | 6 | 7 | 1 | 2 | 3 | 4 | 5 |
| M1 | 100 | 100 | 100 | 100 | 100 | 100 | | 100 | 100 | 100 | 100 | |
| M2 | | | | | | | 100 | | | | | 100 |
| E1 | | | | | 68 | | | | | | | |
| E2 | | | | | | 52 | | | | | 52 | |
| P1 | 40 | 108 | | | 38 | 38 | 28 | | | | | |
| P2 | | | 46 | | | | | | | | | |
| P3 | | | | 33 | | | | | | | | |
| P4 | | | | | | | | 26 | 71 | | | 18 |
| P5 | | | | | | | | | | 31 | 28 | |
| C1 | 1.5 | 1.5 | 1.5 | 1.5 | 1.5 | 1.5 | 1.5 | 1.5 | 1.5 | 1.5 | 1.5 | 1.5 |
| Copper foil peeling strength (kN/m) | 1.2 | 1.2 | 1.1 | 1.3 | 1.4 | 1.3 | 1.3 | 1.0 | 1.0 | 1.0 | 1.1 | 1.1 |
| Interlayer adhesion force (kN/m) | 0.9 | 0.9 | 0.8 | 1.0 | 1.0 | 0.9 | 1.0 | 0.5 | 0.5 | 0.6 | 0.7 | 0.7 |
| Dielectric constant | 2.84 | 2.88 | 2.80 | 2.87 | 2.93 | 2.97 | 2.80 | 2.99 | 3.02 | 3.01 | 3.04 | 2.92 |
| Dielectric loss tangent | 0.0039 | 0.0068 | 0.0035 | 0.0045 | 0.0060 | 0.0065 | 0.0055 | 0.0042 | 0.0073 | 0.0046 | 0.0072 | 0.0060 |
| Tg (°C) | 267 | 221 | 260 | 272 | 235 | 230 | 253 | 265 | 218 | 263 | 214 | 252 |

### INDUSTRIAL APPLICABILITY

The resin composition of the present invention is excellent in dielectric properties, heat resistance, and adhesiveness and can be used in applications of lamination, shape, adhesion, and the like, and in particular, it is useful as electronic materials for high-speed communication equipment.

1. A thermosetting resin composition comprising an aromatic polyhydroxy compound represented by the following formula (1), and a maleimide compound: 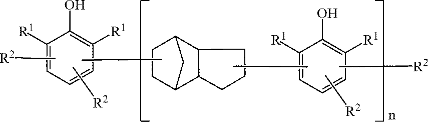
wherein
R¹ independently represents a hydrocarbon group having 1 to 8 carbon atoms,
R² independently represents a hydrogen atom or a dicyclopentenyl group, and at least one
R² is a dicyclopentenyl group, and
n represents the number of repetitions and an average value thereof is a number of 1 to 5.

2. The thermosetting resin composition according to claim 1, further comprising an epoxy resin.

3. A cured product obtained by curing the thermosetting resin composition according to claim 1.

4. A sealing material using the thermosetting resin composition according to claim 1.

5. A material for a circuit substrate using the thermosetting resin composition according to claim 1.

6. A prepreg using the thermosetting resin composition according to claim 1.

7. A laminated board using the thermosetting resin composition according to claim 1.

8. A cured product obtained by curing the thermosetting resin composition according to claim 2.

9. A sealing material using the thermosetting resin composition according to claim 2.

10. A material for a circuit substrate using the thermosetting resin composition according to claim 2.

11. A prepreg using the thermosetting resin composition according to claim 2.

12. A laminated board using the thermosetting resin composition according to claim 2.
